(19) United States
(12) Patent Application Publication
(10) Pub. No.: US 2008/0003832 A1
(43) Pub. Date: Jan. 3, 2008

(54) Method for fabricating recess gate of semiconductor device

(75) Inventors: Ky-Hyun Han, Kyoungki-do (KR); Ki-Won Nam, Kyoungki-do (KR)

Correspondence Address: BLAKELY SOKOLOFF TAYLOR & ZAFMAN, 1279 OAKMEAD PARKWAY, SUNNYVALE, CA, 94085-4040, US

(73) Assignee: Hynix Semiconductor Inc.

(21) Appl. No.: 11/715,524

(22) Filed: Mar. 8, 2007

(30) Foreign Application Priority Data
Jun. 29, 2006 (KR) 2006-0059319

(51) Int. Cl. H01L 21/311

(52) U.S. Cl. 438/702; 257/E21.249

(57) ABSTRACT

A recess pattern is formed in a substrate where an isolation structure is formed. Portions of the substrate are etched to remove a horn generated while forming the recess pattern. A gate insulation layer is formed over the recess pattern and the substrate. A gate structure is formed over the gate insulation layer, covering the recess pattern.

### CROSS-REFERENCE TO RELATED APPLICATIONS

The present invention claims priority of Korean patent application number 10-2006-0059319, filed on Jun. 29, 2006, which is incorporated by reference in its entirety.

### BACKGROUND OF THE INVENTION

The present invention relates to a method for fabricating a semiconductor device, and more particularly, to a method for fabricating a recess gate of a semiconductor device.

As for a typical method for forming a planar gate interconnection line by forming a gate over a flat active region, the current large integration scale of semiconductor devices has caused a channel length to be decreased but an implantation doping concentration to be increased. Accordingly, due to an increased electric field, a junction leakage is generated and thus, it becomes difficult to secure a satisfactory refresh property of a device.

A recess gate process has been suggested to overcome the above described limitations as a method for fabricating a gate interconnection line. The recess gate process forms a gate after etching an active region of a substrate to form a recess pattern. If the recess gate process is applied, the channel length is increased and the implantation doping concentration is decreased. Accordingly, the refresh property of the device can be improved.

FIGS. 1A to 1B illustrate a typical method for fabricating a recess gate of a semiconductor device. FIG. 1C illustrates a cross-sectional view of a resultant structure cut in a line I-I′ of FIG. 1A. FIG. 1D illustrates a cross-sectional view of a resultant structure cut in a line II-II′ of FIG. 1B.

As shown in FIGS. 1A and 1C, an isolation structure 12 is formed in a substrate 11. The substrate 11 in which the isolation structure 12 is formed is etched to a certain thickness to form a plurality of recess patterns 13. As shown in FIGS. 1B and 1D, a gate insulation layer 14 is formed over an entire surface of the above resulting structure including the recess patterns 13.

As described above, a gate length and a channel area are increased by forming the recess patterns 13. Thus, a device property may be improved. However, horns 100 may be generated at edge portions of the recess patterns 13 contacting the isolation structure 12 due to slopes of the recess patterns 13 and the isolation structure 12. Thus, portions where the horns 100 are generated may be vulnerable to electric charges during a subsequent process. Since the electric charges tend to concentrate at a horn-shaped portion due to an electrical property, the electric charges concentrate around the horns 100 when receiving electrical signals. As a result, the gate insulation layer 14 may be easily broken and thus, a threshold voltage may be decreased. The horns 100 will be examined in more detail in FIGS. 2A and 2B.

FIGS. 2A and 2B are transmission electron microscopy (TEM) illustrating a typical recess pattern of a semiconductor device. FIG. 2A illustrates the typical recess pattern cut in the vertical direction, and FIG. 2B illustrates the typical recess pattern cut in the horizontal direction.

Horns 200 are generated at edge portions of recess patterns 23 contacting an isolation structure 22 formed on a substrate 21. After the recess patterns 23 are formed, a gate insulation layer is formed at portions where the horns 200 are generated through performing a thermal oxidation process to a thickness smaller than at another portion. Accordingly, the portions where the horns 200 are generated may have a poor electrical property.

### SUMMARY OF THE INVENTION

Embodiments of the present invention are directed to provide a method for fabricating a recess gate of a semiconductor device capable of minimizing a horn where electric charges concentrate.

In accordance with an aspect of the present invention, there is provided a method for fabricating a recess gate of a semiconductor device. The method includes forming a recess pattern in a substrate where an isolation structure is formed, etching portions of the substrate to remove a horn generated while forming the recess pattern, forming a gate insulation layer over the recess pattern and the substrate, and forming a gate structure covering the recess pattern over the gate insulation layer.

### BRIEF DESCRIPTION OF THE DRAWINGS

FIGS. 1A and 1B illustrate a typical method for fabricating a recess gate of a semiconductor device;

FIGS. 1C and 1D illustrate cross-sectional views of resultant structures cut in lines I-I′ and II-II′ of FIGS. 1A and 1B, respectively.

FIGS. 2A and 2B are transmission electron microscopic (TEM) images illustrating a typical recess pattern of a semiconductor device;

FIGS. 3A to 3D illustrate a method for fabricating a recess gate of a semiconductor device in accordance with an embodiment of the present invention;

FIGS. 4A to 4D illustrate cross-sectional views of resultant structures cut in lines A-A′, B-B′, C-C′, and D-D′ of FIGS. 3A to 3D, respectively; and

FIGS. 5A and 5B are TEM images illustrating a recess pattern of a semiconductor device in accordance with another embodiment of the present invention.

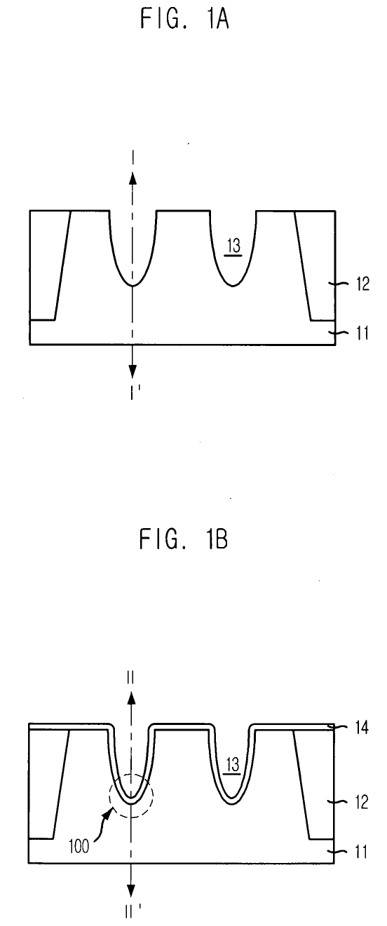

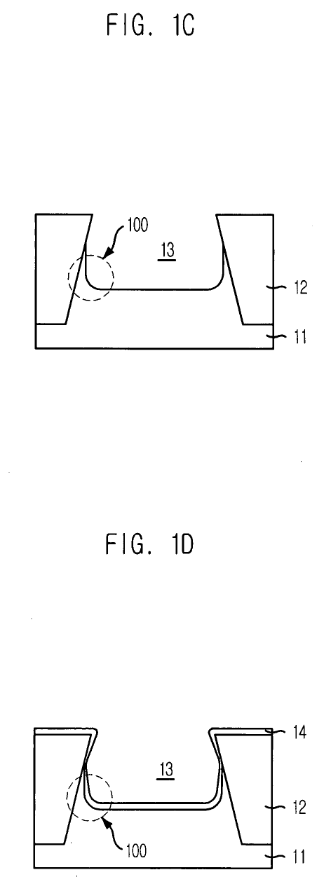

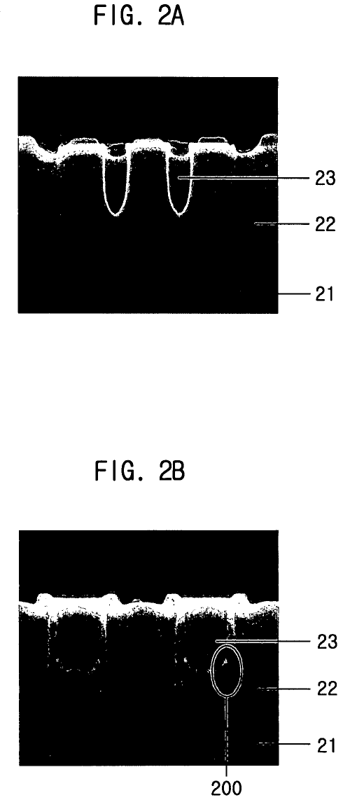

### DESCRIPTION OF SPECIFIC EMBODIMENTS

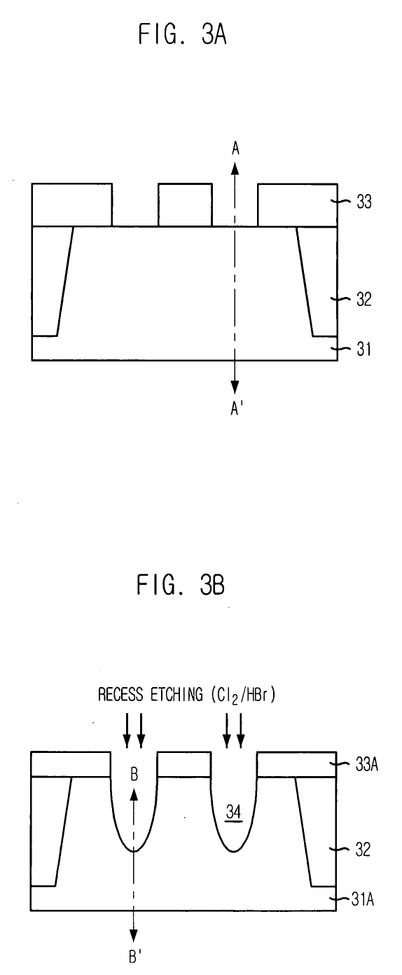

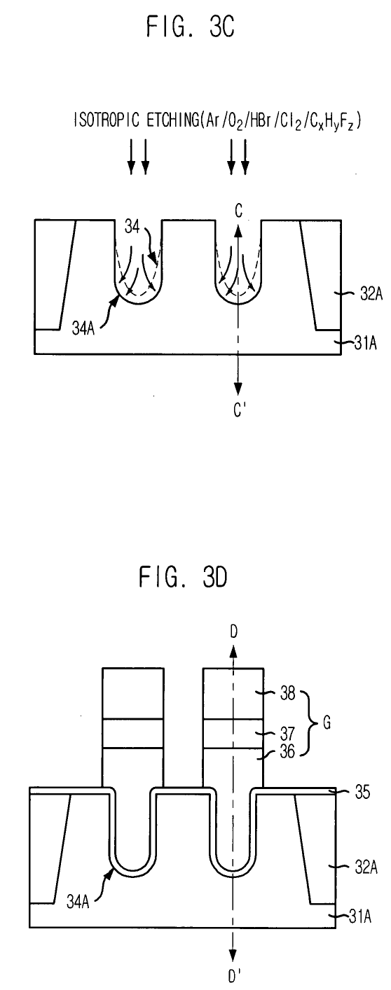

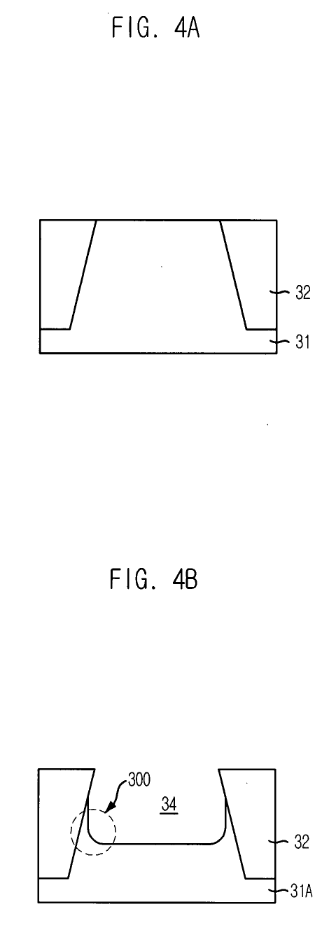

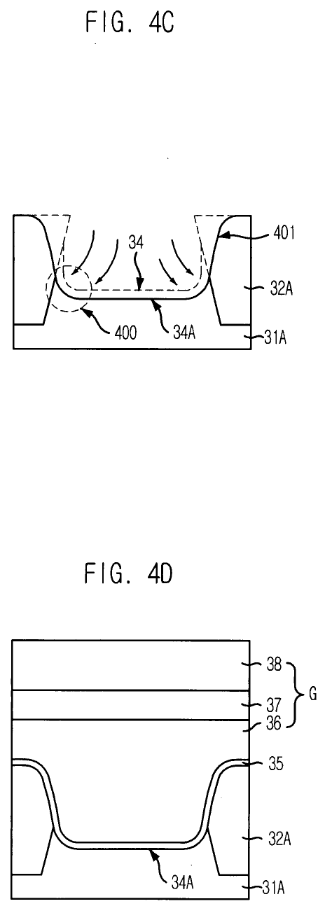

FIGS. 3A to 3D illustrate a method for fabricating a recess gate of a semiconductor device in accordance with an embodiment of the present invention. FIGS. 4A to 4D illustrate cross-sectional views of resultant structures cut in lines A-A′, B-B′, C-C′, and D-D′ of FIGS. 3A to 3D, respectively.

As shown in FIG. 3A, an isolation structure 32 is formed in a substrate 31. The isolation structure 32 defines an active region of the substrate 31. Particularly, isolation regions are etched, and an insulation material is filled in the isolation regions. Then, a planarization process is performed on the insulation material to obtain the isolation structure 32. The isolation structure 32 is formed to a thickness greater than the thickness of subsequent recesses.

A mask pattern 33 is formed over the substrate 31 including the isolation structure 32. The mask pattern 33 functions as a hard mask used to open regions where recess patterns are to be formed. The mask pattern 33 includes polysilicon. In more detail about the formation of the mask pattern 33, a polysilicon layer is formed over the substrate 31 and then, a photoresist layer is formed thereon. Afterwards, a photo-exposure process and a developing process are performed to form a photoresist pattern opening the regions where the recess patterns are to be formed. The polysilicon layer is etched using the photoresist pattern as an etch mask to form the mask pattern 33. The photoresist pattern is removed performing an oxygen removal process.

As shown in FIG. 3B, the substrate 31 is etched using the mask pattern 33 as the hard mask to form a plurality of first recess patterns 34. In particular, the substrate 31 is etched in-situ in the chamber where the mask pattern 33 is formed. A patterned substrate is denoted with reference numeral 31A. The first recess patterns 34 increase a channel length, thereby securing a refresh property. The first recess patterns 34 are formed using a mixture gas including chlorine (Cl₂) gas and hydrogen bromide (HBr) gas with the application of a top power ranging from about 1,000 W to 3,000 W, and a bottom power ranging from about 30 W to 100 W.

When the formation of the first recess patterns 34 is completed, horns 300 (see FIG. 4B) are formed at edge portions of the first recess patterns 34 due to slopes of the first recess patterns 34 and the isolation structure 32. The horns 300 cannot help being produced due to a property of the process. After the formation of the first recess patterns 34, the mask pattern 33 may not remain or remain thin as reference numeral 33A shows.

As shown in FIG. 3C, an etching process is performed to make bottom profiles of the first recess patterns 34 rounded. More specifically, the etching process includes an isotropic etchign process. The recess patterns with the rounded bottom profiles are referred to as second recess patterns and denoted with reference numeral 34A. The isotropic etching process removes the horns 300 (see FIG. 4B) produced at the edge portions of the first recess patterns 34 contacting the isolation structure 32, and makes the bottom profiles of the first recess patterns 34 rounded. Reference numeral 400 illustrates the rounded bottom profiles of the second recess patterns 34A.

The isotropic etching process includes using a top power (e.g., in a range of about 700 W to 2,000 W) without a bottom power or using both of the top power and the bottom power simultaneously. An isotropic etching property can be maximized using a top power ranging from about 700 W to about 2,000 W and a low bottom power ranging from about 1 W to about 20 W.

If the isotropic etching process is performed only using the top power as the bottom power remains none or low, light ions having a great energy in a plasma composition cannot reach the bottom portion of silicon because the low bottom power is exerted. The ions are distributed over sidewalls of the first recess patterns 34 where the horns 300 (see FIG. 4B) exist and thus, etching the sidewalls of the first recess patterns 34. Heavy radical ions performing a chemical etch in the plasma composition are distributed over bottom portions of the first recess patterns 34 and thus, etches the bottom portions of the first recess patterns 34.

The etch is performed over the sidewalls of the first recess patterns 34 faster than over the bottom portions of the first recess patterns 34. As a result, the horns 300 (see FIG. 4B) can be minimized, and the bottom profiles of the first recess patterns 34 can be rounded.

As mentioned above, the top power is applied in a range between about 700 W and 2,000 W. If the top power greater than about 2,000 W is applied, the top portions of the first recess patterns 34 exposed after the removal of the remaining mask pattern 33A are lost. The lost top portions of the first recess patterns 34 may be prone to leakage current. If the top power lower than about 700 W is applied, the horns 300 may not be minimized. Thus, one exemplary range of the top power that provides a desired effect may range between about 700 W and 2,000 W.

In addition to the control of the top and bottom power, the isotropic etching process includes using a mixture gas including a trace amount of CₓH_{y}F_{z}, where x, y and z each range between about 1 to 10. The mixture gas also includes argon (Ar), oxygen (O₂), chlorine (Cl₂), and hydrogen bromide (HBr) gases. A flow rate of the Ar gas ranges from about 200 sccm to about 400 sccm. A flow rate of the O₂ gas ranges from about 100 sccm to about 250 sccm. A flow rate of the HBr gas ranges from about 20 sccm to about 40 sccm. A flow rate of the Cl₂ gas ranges from about 5 sccm to about 15 sccm. One exemplary gas of CₓH_{y}F_{z} includes CHF₃ gas, and a flow rate of the CHF₃ gas is in a range of about 5 sccm to 40 sccm.

The above mixture gas provides isotropic etch characteristics. In particular, even though a trace amount of CₓH_{y}F_{z} gas is used, the bottom portions of the first recess patterns 34 can be maximally rounded as reference numeral 34A shows. Also, the mixture gas allows the isolation structure 32 (e.g., an oxide-based material) to be isotropically etched, so as to form a patterned isolation structure 32A with rounded portions 401. Due to the rounded isolation structure 32A, an insulation layer for a gate structure can be formed to a uniform thickness.

The gases for the isotropic etching process are not clearly separated into the ions and the radical ions. However, the ions and the radical ions are generated due to the reaction and separation of the gases in a plasma state. For instance, the HBr gas is separated into H⁺ and Br⁻ ions in the plasma state. However, radical ions such as H₂Br⁺ or ions such as HBr₂⁻ are produced due to a row association of ions, thereby strengthening the chemical reactivity. The radical ions are heavier than the individual ions. Accordingly, when a low bottom power is exerted, the ions can freely move due to lack of gravitation and thus, the ions are distributed over the sidewalls of the first recess patterns 34 where the horns 300 (see FIG. 4B) exist. As a result, the ions etch the sidewalls of the first recess patterns 34. The radical ions cannot freely move as much as the ions and thus, the radical ions are distributed over the bottom portions of the first recess patterns 34. As a result, the radical ions etch the bottom portions reacting with materials forming the bottom portions.

The isotropic etching process is performed in-situ in the same chamber used to perform the etching process to form the first recess patterns 34.

If the horns 300 (see FIG. 4B) formed at the edge portions of the first recess patterns 34 are removed, and the bottom profiles of the first recess patterns 34 contacting the isolation structure 32 are rounded through performing the isotropic etching process, the electric charges do not concentrate at the portions where the horns 300 (see FIG. 4B) are generated. Accordingly, a subsequent gate insulation layer is not easily broken, thereby preventing a decrease in a threshold voltage.

As shown in FIG. 3D, a gate insulation layer 35 is formed over an entire surface of the above resulting structure including the second recess patterns 34A. The gate insulation layer 35 is formed of an oxide layer by way of a thermal oxidation process or a plasma oxidation process. Particularly, the gate insulation layer 35 can be formed to a uniform thickness since the horns 300 (see FIG. 4B) formed at the edge portions of the first recess patterns 34 contacting the isolation structure 32 are removed, and the bottom profiles of the first recess patterns 34 are rounded through performing the isotropic etching process. Accordingly, a typical limitation which a gate insulation layer is easily broken due to a small deposition thickness can be overcome, thereby securing an electrical property.

A plurality of gate patterns G, having first portions filled into the second recess patterns 34A and second portions projected over an upper portion of the patterned substrate 31A are formed over the gate insulation layer 35. Each of the gate patterns G is formed in a stack structure of a polysilicon electrode 36, a metal electrode 37, and a gate hard mask 38. The metal electrode 37 includes tungsten or tungsten silicide. As described above, a structure having a first portion filled into each of the second recess patterns 34A and a second portion projected over the upper portion of the patterned substrate 31A is referred to as a recess gate.

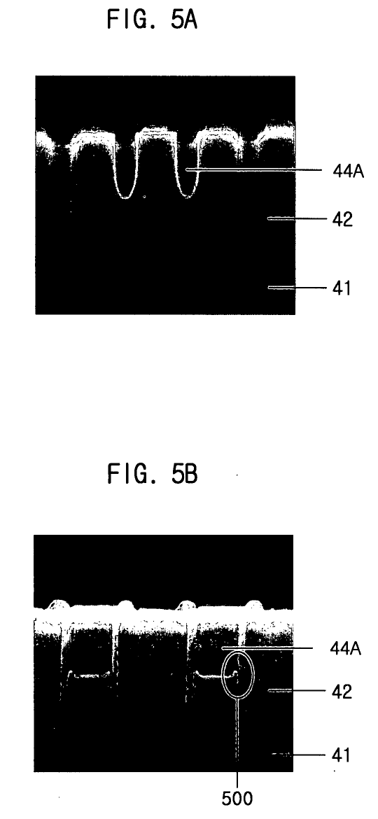

FIGS. 5A and 5B are transmission electron microscopy (TEM) illustrating a recess pattern of a semiconductor device in accordance with another embodiment of the present invention. FIG. 5A illustrates the recess pattern cut in the vertical direction, and FIG. 5B illustrates the recess pattern cut in the horizontal direction. After an isotropic etching process, horns 500, which are formed at edge portions of recess patterns contacting an isolation structure 42 formed over a substrate 41, are less generated (or removed), and rounded. Thus, bottom profiles of the recess patterns can be rounded, thereby providing rounded recess patterns as reference numeral 44A represents.

As described above, after the recess pattern is formed, the isotropic etching process is performed to minimize the horn formed at the edge portion of the recess pattern contacting the isolation structure and to make the bottom profile of the recess pattern rounded. As a result, a phenomenon which the electric charges concentrate at a portion where the horn is generated can be prevented, and the subsequent gate insulation layer can be formed to a uniform thickness. Accordingly, it is possible to secure an electrical property.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a recess gate of a semiconductor device, comprising:
forming a recess pattern in a substrate where an isolation structure is formed;
etching portions of the substrate to remove a horn generated while forming the recess pattern;
forming a gate insulation layer over the recess pattern and the substrate; and
forming a gate structure covering the recess pattern over the gate insulation layer.

2. The method of claim 1, wherein etching the portions of the substrate comprises performing an isotropic etching process.

3. The method of claim 2, wherein etching the portions of the substrate comprises using a top power.

4. The method of claim 3, wherein the top power ranges from about 700 W to 2,000 W.

5. The method of claim 2, wherein etching the portions of the substrate comprises using a top power and a bottom power.

6. The method of claim 5, wherein the top power ranges from about 700 W to 2,000 W and the bottom power ranges from about 1 W to 20 W.

7. The method of claim 1, wherein forming the recess pattern comprises:
forming a polysilicon layer over the substrate;
etching the polysilicon layer to form a mask pattern; and
etching the substrate using the mask pattern as a hard mask.

8. The method of claim 7, wherein etching the polysilicon layer and etching the substrate are performed in situ in the same chamber with using substantially the same etch gas.

9. The method of claim 8, wherein etching the polysilicon layer and etching the substrate comprises using a mixture gas including chlorine (Cl₂) gas and hydrogen bromide (HBr) gas.

10. The method of claim 1, wherein forming the recess pattern and etching the portions of the substrate are performed in situ in the same chamber.

11. The method of claim 1, wherein etching the portions of the substrate comprises using a mixture gas including at least CₓH_{y}F_{z} gas, where x, y and z are positive numbers.

12. The method of claim 11, wherein the CₓH_{y}F_{z} gas comprises CHF₃ gas.

13. The method of claim 11, wherein the mixture gas further comprises argon (Ar) gas, oxygen (O₂) gas, hydrogen bromide (HBr) gas, and chlorine (Cl₂) gas.

14. The method of claim 13, wherein the Ar gas flows at a rate of about 200 sccm to 400 sccm.

15. The method of claim 13, wherein the O₂ gas flows at a rate of about 100 sccm to 250 sccm.

16. The method of claim 13, wherein the HBr gas flows at a rate of about 20 sccm to 40 sccm.

17. The method of claim 13, wherein the Cl₂ gas flows at a rate of about 5 sccm to 15 sccm.
